(19) United States
(12) Patent Application Publication
(10) Pub. No.: US 2024/0160149 A1
(43) Pub. Date: May 16, 2024

(54) Systems and Methods for Fabricating a Multilayer Optical Structure

(71) Applicant: DigiLens Inc., Sunnyvale, CA (US)

(72) Inventors: Jonathan David Waldern, Los Altos Hills, CA (US); Alastair John Grant, San Jose, CA (US); Milan Momcilo Popovich, Leicester (GB)

(73) Assignee: DigiLens Inc., Sunnyvale, CA (US)

(21) Appl. No.: 18/353,786

(22) Filed: Jul. 17, 2023

Related U.S. Application Data
(63) Continuation of application No. 17/816,240, filed on Jul. 29, 2022, now abandoned.
Application No. 17/816,240 is a continuation of application No. 16/522,491, filed on Jul. 25, 2019, now Pat. No. 11,402,801.
(60) Provisional application No. 62/703,329, filed on Jul. 25, 2018.

(51) Int. Cl. G03H 1/02; B05D 1/00; B05D 1/02; B05D 5/06; F21V 8/00; G02B 5/18; G03F 7/00

(52) U.S. Cl. CPC G03H 1/0248; B05D 1/005; B05D 1/02; B05D 5/061; G02B 5/1857; G02B 6/0065; G03F 7/001; G03H 2001/0441; G03H 2260/12; G03H 2260/33

(57) ABSTRACT

Systems and methods for fabricating optical elements in accordance with various embodiments of the invention are illustrated. One embodiment includes a method for fabricating an optical element, the method including providing a first optical substrate, depositing a first layer of a first optical recording material onto the first optical substrate, applying an optical exposure process to the first layer to form a first optical structure, temporarily erasing the first optical structure, depositing a second layer of a second optical recording material, and applying an optical exposure process to the second layer to form a second optical structure, wherein the optical exposure process includes using at least one light beam traversing the first layer.

### CROSS-REFERENCE TO RELATED APPLICATIONS

The current application is a continuation of U.S. patent application Ser. No. 17/816,240 entitled “Systems and Methods for Fabricating a Multilayer Optical Structure,” filed Jul. 29, 2022, which is a continuation of U.S. patent application Ser. No. 16/522,491 entitled “Systems and Methods for Fabricating a Multilayer Optical Structure,” filed Jul. 25, 2019, which claims the benefit of and priority under 35 U.S.C. § 119(e) to U.S. Provisional Patent Application No. 62/703,329 entitled “Systems and Methods for Fabricating a Multilayer Optical Structure,” filed Jul. 25, 2018, the disclosures of which are hereby incorporated by reference in their entireties.

### FIELD OF THE INVENTION

The present disclosure relates to methods for fabricating multilayer optical devices and, more particularly, to methods for fabricating multilayer holographic waveguide devices using a liquid crystal and polymer material.

### BACKGROUND

Waveguides can be referred to as structures with the capability of confining and guiding waves (i.e., restricting the spatial region in which waves can propagate). One subclass includes optical waveguides, which are structures that can guide electromagnetic waves, typically those in the visible spectrum. Waveguide structures can be designed to control the propagation path of waves using a number of different mechanisms. For example, planar waveguides can be designed to utilize diffraction gratings to diffract and couple incident light into the waveguide structure such that the in-coupled light can proceed to travel within the planar structure via total internal reflection (“TIR”).

Fabrication of waveguides can include the use of material systems that allow for the recording of holographic optical elements within the waveguides. One class of such material includes polymer dispersed liquid crystal (“PDLC”) mixtures, which are mixtures containing photopolymerizable monomers and liquid crystals. A further subclass of such mixtures includes holographic polymer dispersed liquid crystal (“HPDLC”) mixtures. Holographic optical elements, such as volume phase gratings, can be recorded in such a liquid mixture by illuminating the material with two mutually coherent laser beams. During the recording process, the monomers polymerize and the mixture undergoes a photopolymerization-induced phase separation, creating regions densely populated by liquid crystal micro-droplets, interspersed with regions of clear polymer. The alternating liquid crystal-rich and liquid crystal-depleted regions form the fringe planes of the grating.

Waveguide optics, such as those described above, can be considered for a range of display and sensor applications. In many applications, waveguides containing one or more grating layers encoding multiple optical functions can be realized using various waveguide architectures and material systems, enabling new innovations in near-eye displays for augmented reality (“AR”) and virtual reality (“VR”), compact heads-up displays (“HUDs”) for aviation and road transport, and sensors for biometric and laser radar (“LIDAR”) applications.

### SUMMARY OF THE INVENTION

Systems and methods for fabricating optical elements in accordance with various embodiments of the invention are illustrated. One embodiment includes a method for fabricating an optical element, the method including providing a first optical substrate, depositing a first layer of a first optical recording material onto the first optical substrate, applying an optical exposure process to the first layer to form a first optical structure, temporarily erasing the first optical structure, depositing a second layer of a second optical recording material, and applying an optical exposure process to the second layer to form a second optical structure, wherein the optical exposure process includes using at least one light beam traversing the first layer.

In another embodiment, the method further includes providing a second optical substrate, wherein the second layer is deposited onto the second optical substrate, and overlapping the second optical substrate with the first optical substrate.

In a further embodiment, the second optical substrate is laterally or rotationally displaced relative to the first optical substrate.

In still another embodiment, the method further includes applying a first cover layer to the first layer and applying a second cover layer to the second layer.

In a still further embodiment, the at least one light beam is provided by an apparatus selected from the group that includes: a crossed-beam holographic recording apparatus; a contact copying apparatus using a master grating or hologram; and an apparatus for traversing light with a predefined beam cross section.

In yet another embodiment, the first optical structure is temporarily erased by applying an external stimulus.

In a yet further embodiment, the external stimulus includes a stimulus selected from the group that includes: an optical stimulus, a thermal stimulus, a chemical stimulus, a mechanical stimulus, an electrical stimulus, and a magnetic stimulus.

In another additional embodiment, the external stimulus is applied at a strength below a predefined threshold to produce optical noise below a predefined level.

In a further additional embodiment, the method further includes temporarily erasing the second optical structure, depositing a third layer of a third optical recording material, applying an optical exposure process to the third layer to form a third optical structure using at least one light beam traversing the first layer and the second layer.

In another embodiment again, at least one of the first and second optical structures modifies at least one of phase, amplitude, and wavefront of incident light.

In a further embodiment again, the first optical recording material and the second optical recording material include different material formulations.

In still yet another embodiment, the first optical recording material includes a mixture of liquid crystal and polymer and the first optical structure includes at least one grating.

In a still yet further embodiment, the first optical recording material further includes at least one of: a LPP, a dye, a photoinitiator, a surfactant, a multi-function monomer, and nanoparticles.

In still another additional embodiment, temporarily erasing the first optical structure includes changing the order parameter of the liquid crystal.

In a still further additional embodiment, the first optical recording material includes a liquid crystal, polymer, and an additive for temporarily erasing the first optical structure.

In still another embodiment again, the first optical recording material is deposited onto the first optical substrate using spin coating or inkjet printing.

In a still further embodiment again, the first optical substrate is curved.

In yet another additional embodiment, the method further includes at least one of the steps of: forming an air gap; applying a layer of low refractive index material; applying a polarization control layer; and applying a liquid crystal alignment layer.

In a yet further additional embodiment, the method forms part of a roll-to-roll fabrication process.

A yet another embodiment again includes a method of fabricating an optical element, the method including providing first and second optical substrates, forming a first cell from the first and second substrates, filling the first cell with a first optical recording material, applying an optical exposure process to the first cell to form a first optical structure, temporarily erasing the first optical structure, providing third and fourth optical substrates, forming a second cell from the third and fourth substrates, filling the second cell with a second optical recording material, overlapping the first and second cells, and applying an optical exposure process to the second layer to form a second optical structure, wherein the optical exposure process includes using at least one light beam traversing the first layer.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings, which forms a part of this disclosure.

### BRIEF DESCRIPTION OF THE DRAWINGS

The description will be more fully understood with reference to the following figures and data graphs, which are presented as exemplary embodiments of the invention and should not be construed as a complete recitation of the scope of the invention. It will apparent to those skilled in the art that the present invention may be practiced with some or all of the present invention as disclosed in the following description.

FIGS. 1A and 1B conceptually illustrate different views of a waveguide providing a total internal reflection light guiding structure.

FIG. 2A-2F conceptually illustrate a method for recording a stack of two gratings in accordance with an embodiment of the invention.

FIG. 3A conceptually illustrates an ordered liquid crystal phase.

FIG. 3B conceptually illustrates a disordered liquid crystal phase.

FIG. 4 conceptually illustrates a flow chart of a method for fabricating a multi-waveguide layer stack in accordance with an embodiment of the invention.

FIG. 5 conceptually illustrates a flow chart of a method for fabricating a multi-waveguide layer stack having two grating layers separated by a substrate in accordance with an embodiment of the invention.

FIG. 6 conceptually illustrates a flow chart of a method for fabricating a multi-waveguide layer stack having two grating layers each encapsulated within a cell in accordance with an embodiment of the invention.

### DETAILED DESCRIPTION

Following below are more detailed descriptions of various concepts related to, and embodiments of, optical displays, methods for fabricating optical displays, and methods for displaying information. It should be appreciated that various concepts introduced and discussed below may be implemented in any of numerous ways, as the disclosed concepts are not limited to any particular manner of implementation. Examples of specific implementations and applications are provided primarily for illustrative purposes. A more complete understanding of the invention can be obtained by considering the following detailed description in conjunction with the accompanying drawings, wherein like index numerals indicate like parts. For the purposes of describing embodiments, some well-known features of optical technology known to those skilled in the art of optical design and visual displays have been omitted or simplified in order to not obscure the basic principles of the invention. Unless otherwise stated, the term “on-axis” in relation to a ray or a beam direction refers to propagation parallel to an axis normal to the surfaces of the optical components described in relation to the invention. In the following description the terms light, ray, beam, and direction may be used interchangeably and in association with each other to indicate the direction of propagation of electromagnetic radiation along rectilinear trajectories. The term light and illumination may be used in relation to the visible and infrared bands of the electromagnetic spectrum. Parts of the following description will be presented using terminology commonly employed by those skilled in the art of optical design. As used herein, the term grating may encompass a grating comprised of a set of gratings in some embodiments. For illustrative purposes, it is to be understood that the drawings are not drawn to scale unless stated otherwise.

Waveguides can be stacked to combine different spectral bandwidths, angular bandwidths, and various other optical functions. However, stacking and aligning waveguides can introduce the risk of planarity and contamination and can increase the overall processing time and costs. One method for fabricating multilayer holographic waveguide devices includes stacking waveguide cells and recording holographic elements on the complete stack. However, in such methods, a recorded grating in one layer can deflect the beams traversing it to corrupt a second grating. Similar problems can arise in other processes for manufacturing devices containing multiple layers supporting optical structures. As such, many systems and methods in accordance with various embodiments of the invention are designed to provide optically efficient, economical solutions for fabricating multilayer optical devices, such as but not limited to holographic waveguide devices.

Solutions for fabricating multilayer optical devices in accordance with various embodiments of the invention can include a variety of different techniques, including but not limited to methods for recording optical structures into layers of optical recording material for waveguide stacks of two or more overlapping layers. In many embodiments, the fabrication process includes fabricating a stack of optical structures in which a first optical recording material layer deposited on a substrate is exposed to form a first optical structure, which can be temporarily erased so that a second optical structure can be recorded into a second material layer deposited onto the first layer using optical recording beams traversing the first layer. Optical structures can include but are not limited to gratings. Temporarily “erased” optical structures or gratings can behave similar to transparent materials, allowing light to pass through without affecting the ray paths. This principle can be applied to fabricate a variety of different waveguide stack configurations. For example, some processes include fabricating a multilayer waveguide stack with two grating layers that are separated by a substrate. In some embodiments, the two grating layers are each covered by a protective cover layer. In several embodiments, the process includes fabricating a multilayer waveguide stack with two grating layers that are each encapsulated in a cell. In a number of embodiments, the process is implemented as part of a roll-to-roll fabrication process. These and other configurations and methods for fabricating such configurations are discussed in the sections below in further detail.

### Holographic Waveguide Devices

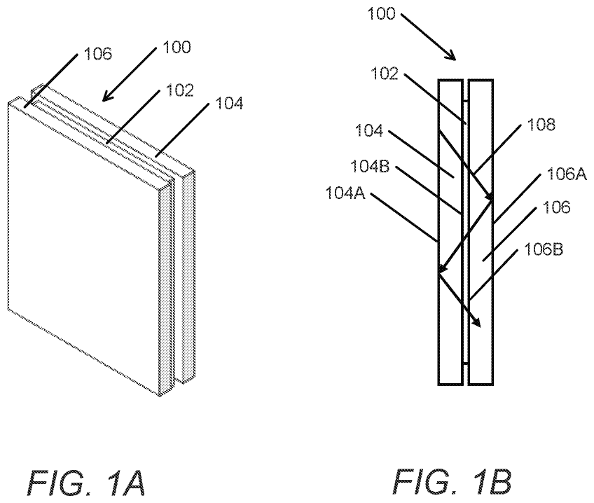

Holographic waveguide devices and related methods of manufacturing in accordance with various embodiments of the invention can be configured in many different ways. In several embodiments, the device includes an optical waveguide that is formed with a grating layer sandwiched between two transparent substrates. In such configurations, the waveguide can provide a total internal reflection (“TIR”) light guiding structure using the substrate-air interfaces. Light traveling within the waveguide via TIR can be coupled out of the waveguide when a grating within the grating layer diffracts the light at an angle beyond the TIR condition. An example of a waveguide utilizing TIR to propagate incident light rays is conceptually illustrated in FIGS. 1A and 1B. FIG. 1A conceptually illustrates a perspective view of the waveguide 100 having a grating layer 102 sandwiched by transparent substrates 104, 106. Various types of materials can be used to form the grating layer and substrates. In many embodiments, the substrates are made of glass or plastic polymers while the grating layer is formed from an HPDLC mixture. FIG. 1B shows the waveguide 100 in operation with a ray 108 traveling between the waveguide outer surfaces 104A, 106A via TIR. As shown, the grating layer 102 is in contact with the substrate surfaces 104B, 106B.

In many display applications, a holographic waveguide device can be implemented with an optical structure that includes a layer containing one or more volume holograms or gratings. Optical structures in accordance with various embodiments of the invention can include various configurations of gratings. In many embodiments, the optical structure includes grating configuration for two-dimensional beam expansion. For example, many optical structures include a fold grating for vertical beam expansion and beam steering and an output grating for horizontal beam expansion and extraction of light from the waveguide. Some optical structures include an input coupler for the waveguide, which can take the form of an input grating or prism. In several embodiments, the input coupler is a surface relief grating. In other embodiments, the input coupler is a volume grating.

Optical structures recorded in waveguides can include many different types of optical elements, such as but not limited to diffraction gratings. In many embodiments, the grating implemented is a Bragg grating (also referred to as a volume grating). Bragg gratings can have high efficiency with little light being diffracted into higher orders. The relative amount of light in the diffracted and zero order can be varied by controlling the refractive index modulation of the grating, a property that is can be used to make lossy waveguide gratings for extracting light over a large pupil. One class of gratings used in holographic waveguide devices is the Switchable Bragg Grating (“SBG”). SBGs can be fabricated by first placing a thin film of a mixture of photopolymerizable monomers and liquid crystal material between glass plates or substrates. In many cases, the glass plates are in a parallel configuration. One or both glass plates can support electrodes, typically transparent tin oxide films, for applying an electric field across the film. The grating structure in an SBG can be recorded in the liquid material (often referred to as the syrup) through photopolymerization-induced phase separation using interferential exposure with a spatially periodic intensity modulation. Factors such as but not limited to control of the irradiation intensity, component volume fractions of the materials in the mixture, and exposure temperature can determine the resulting grating morphology and performance. As can readily be appreciated, a wide variety of materials and mixtures can be used depending on the specific requirements of a given application. In many embodiments, HPDLC material is used. During the recording process, the monomers polymerize and the mixture undergoes a phase separation. The LC molecules aggregate to form discrete or coalesced droplets that are periodically distributed in polymer networks on the scale of optical wavelengths. The alternating liquid crystal-rich and liquid crystal-depleted regions form the fringe planes of the grating, which can produce Bragg diffraction with a strong optical polarization resulting from the orientation ordering of the LC molecules in the droplets.

The resulting volume phase grating can exhibit very high diffraction efficiency, which can be controlled by the magnitude of the electric field applied across the film. When an electric field is applied to the grating via transparent electrodes, the natural orientation of the LC droplets can change, causing the refractive index modulation of the fringes to lower and the hologram diffraction efficiency to drop to very low levels. Typically, the electrodes are configured such that the applied electric field will be perpendicular to the substrates. In a number of embodiments, the electrodes are fabricated from indium tin oxide (“ITO”). In the OFF state with no electric field applied, the extraordinary axis of the liquid crystals generally aligns normal to the fringes. The grating thus exhibits high refractive index modulation and high diffraction efficiency for P-polarized light. When an electric field is applied to the HPDLC, the grating switches to the ON state wherein the extraordinary axes of the liquid crystal molecules align parallel to the applied field and hence perpendicular to the substrate. In the ON state, the grating exhibits lower refractive index modulation and lower diffraction efficiency for both S- and P-polarized light. Thus, the grating region no longer diffracts light. Each grating region can be divided into a multiplicity of grating elements such as for example a pixel matrix according to the function of the HPDLC device. Typically, the electrode on one substrate surface is uniform and continuous, while electrodes on the opposing substrate surface are patterned in accordance to the multiplicity of selectively switchable grating elements.

Typically, the SBG elements are switched clear in 30 μs with a longer relaxation time to switch ON. Note that the diffraction efficiency of the device can be adjusted, by means of the applied voltage, over a continuous range. In many cases, the device exhibits near 100% efficiency with no voltage applied and essentially zero efficiency with a sufficiently high voltage applied. In certain types of HPDLC devices, magnetic fields can be used to control the LC orientation. In some HPDLC applications, phase separation of the LC material from the polymer can be accomplished to such a degree that no discernible droplet structure results. An SBG can also be used as a passive grating. In this mode, its chief benefit is a uniquely high refractive index modulation. SBGs can be used to provide transmission or reflection gratings for free space applications. SBGs can be implemented as waveguide devices in which the HPDLC forms either the waveguide core or an evanescently coupled layer in proximity to the waveguide. The glass plates used to form the HPDLC cell provide a total internal reflection (“TIR”) light guiding structure. Light can be coupled out of the SBG when the switchable grating diffracts the light at an angle beyond the TIR condition.

One of the known attributes of transmission SBGs is that the LC molecules tend to align with an average direction normal to the grating fringe planes (i.e., parallel to the grating or K-vector). The effect of the LC molecule alignment is that transmission SBGs efficiently diffract P polarized light (i.e., light with a polarization vector in the plane of incidence), but have nearly zero diffraction efficiency for S polarized light (i.e., light with the polarization vector normal to the plane of incidence). As a result, transmission SBGs typically cannot be used at near-grazing incidence as the diffraction efficiency of any grating for P polarization falls to zero when the included angle between the incident and reflected light is small. In addition, illumination light with non-matched polarization is not captured efficiently in holographic displays sensitive to one polarization only.

In some cell designs, adhesives and spacers can be disposed between the substrates to affix the layers of the elements together and to maintain the cell gap, or thickness dimension. In these devices, spacers can take many forms, such as but not limited to different materials, sizes, and geometries. Materials can include, for example, plastics (e.g., divinylbenzene), silica, and conductive spacers. They can take any suitable geometry, such as but not limited to rods and spheres. The spacers can take any suitable size. In many cases, the sizes of the spacers range from 1 to 30 μm. While the use of these adhesive materials and spacers can be necessary in LC cells using conventional materials and methods of manufacture, they can contribute to the haziness of the cells degrading the optical properties and performance of the waveguide and device.

Waveguides and associated optical structures can be fabricated using a variety of different methods. In many embodiments, a waveguide is fabricated by coating a first substrate with an optical recording material. In a number of embodiments, the optical recording material is deposited onto the substrates using spin coating or spraying. A second substrate layer can be included to form the waveguide such that the optical recording material is sandwiched between two substrates. In several embodiments, the second substrate can be a thin protective film coated onto the exposed layer. In various embodiments, the substrates are used to make a cell, which is then filled with the holographic recording material. The filling process can be accomplished using a variety of different methods, such as but not limited vacuum filling methods. In further embodiments, alignment layers and/or polarization layers can be added. As can readily be appreciated, the fabrication methods described can be applied to fabricate a wide variety of waveguides with different optical structures, such as but not limited to diffraction gratings. For example, fabrication methods in accordance with various embodiments of the invention can include recording an SBG by coating an optical recording material onto a substrate, which is exposed and then sealed by a protective overcoat layer.

Various recording methods can be used for fabricating optical structures in accordance with many embodiments of the invention. In mass production, it can be more efficient and cost effective to replace the traditional two beam holographic recording processes with one using contact printing from a master. In some embodiments, the gratings are recorded using mastering and contact copying process. In several embodiments, the grating in a given layer can be recorded in stepwise fashion by scanning or stepping the recording laser beams across the grating area.

In many applications, a waveguide stack of two or more waveguides is implemented for various purposes. For example, two or more waveguides can be stacked to combine different spectral bandwidths, angular bandwidths, and/or optical functions. Such waveguide stacks can be formed with waveguides that are overlaid. In many embodiments, the waveguides are overlaid in contact. In other embodiments, the waveguides are overlaid with air gap(s) or other layer(s) in between. Methods for manufacturing multilayer waveguide devices can include the use of certain materials that allow for the individual recording of the optical structure within each of the layer within the waveguide device. In the case of holographic waveguide embodiments, the optical recording material forming the grating layer can include a liquid crystal (“LC”) polymer mixture. Such material systems can allow the grating to be temporarily erased through the application of external stimuli that alter the alignment of the LC so that the LC index matches that of the surrounding polymer. Although discussions may describe the recording of optical structures having at least one holographic grating formed in layers in waveguide devices, various embodiments in accordance with the invention may also be applied to the recording of more general optical structures for modifying at least one of phase, amplitude, or wavefront of incident light in liquid crystal and polymer material systems. Examples of material systems used in the fabrication processes of various optical devices incorporating waveguides with holographic gratings can include PDLC mixtures and formulations. Discussions of PDLC material systems are described in further detail in the sections below. Although the discussions concentrate on LC polymer material systems, various embodiments in accordance with the invention can be applied using other material systems capable of supporting optical structures that can be erased by an external stimulus.

### Optical Recording Material Systems

PDLC mixtures in accordance with various embodiments of the invention generally include LC, monomers, photoinitiator dyes, and coinitiators. The mixture (often referred to as syrup) frequently also includes a surfactant. For the purposes of describing the invention, a surfactant is defined as any chemical agent that lowers the surface tension of the total liquid mixture. The use of surfactants in PDLC mixtures is known and dates back to the earliest investigations of PDLCs. For example, a paper by R. L Sutherland et al., SPIE Vol. 2689, 158-169, 1996, the disclosure of which is incorporated herein by reference, describes a PDLC mixture including a monomer, photoinitiator, coinitiator, chain extender, and LCs to which a surfactant can be added. Surfactants are also mentioned in a paper by Natarajan et al, Journal of Nonlinear Optical Physics and Materials, Vol. 5 No. I 89-98, 1996, the disclosure of which is incorporated herein by reference. Furthermore, U.S. Pat. No. 7,018,563 by Sutherland; et al., discusses polymer-dispersed liquid crystal material for forming a polymer-dispersed liquid crystal optical element comprising: at least one acrylic acid monomer; at least one type of liquid crystal material; a photoinitiator dye; a coinitiator; and a surfactant. The disclosure of U.S. Pat. No. 7,018,563 is hereby incorporated by reference in its entirety.

The patent and scientific literature contains many examples of material systems and processes that can be used to fabricate SBGs, including investigations into formulating such material systems for achieving high diffraction efficiency, fast response time, low drive voltage, and so forth. U.S. Pat. No. 5,942,157 by Sutherland, and U.S. Pat. No. 5,751,452 by Tanaka et al. both describe monomer and liquid crystal material combinations suitable for fabricating SBG devices. Examples of recipes can also be found in papers dating back to the early 1990s. Many of these materials use acrylate monomers, including:
R. L. Sutherland et al., Chem. Mater. 5, 1533 (1993), the disclosure of which is incorporated herein by reference, describes the use of acrylate polymers and surfactants. Specifically, the recipe comprises a crosslinking multifunctional acrylate monomer; a chain extender N-vinyl pyrrolidinone, LC E7, photo-initiator rose Bengal, and coinitiator N-phenyl glycine. Surfactant octanoic acid was added in certain variants.
Fontecchio et al., SID 00 Digest 774-776, 2000, the disclosure of which is incorporated herein by reference, describes a UV curable HPDLC for reflective display applications including a multi-functional acrylate monomer, LC, a photoinitiator, a coinitiators, and a chain terminator.
Y. H. Cho, et al., Polymer International, 48, 1085-1090, 1999, the disclosure of which is incorporated herein by reference, discloses HPDLC recipes including acrylates.
Karasawa et al., Japanese Journal of Applied Physics, Vol. 36, 6388-6392, 1997, the disclosure of which is incorporated herein by reference, describes acrylates of various functional orders.
T. J. Bunning et al., Polymer Science: Part B: Polymer Physics, Vol. 35, 2825-2833, 1997, the disclosure of which is incorporated herein by reference, also describes multifunctional acrylate monomers.
G. S. lannacchione et al., Europhysics Letters Vol. 36 (6). 425-430, 1996, the disclosure of which is incorporated herein by reference, describes a PDLC mixture including a penta-acrylate monomer, LC, chain extender, coinitiators, and photoinitiator.

Acrylates offer the benefits of fast kinetics, good mixing with other materials, and compatibility with film forming processes. Since acrylates are cross-linked, they tend to be mechanically robust and flexible. For example, urethane acrylates of functionality 2 (di) and 3 (tri) have been used extensively for HPDLC technology. Higher functionality materials such as penta and hex functional stems have also been used.

### Fabrication Methods for Multilayer Waveguide Stacks

The fabrication of multilayer optical devices in accordance with various embodiments of the invention can include a variety of different techniques. Methods for recording optical structures into layers of optical recording material can be implemented for waveguide stacks with overlapping layers. Such recording methods can include fabricating a stack of optical structures in which a first optical recording material layer deposited on a substrate is exposed to form a first optical structure, which can be temporarily erased so that a second optical structure can be recorded into a second material layer deposited onto the first layer using optical recording beams traversing the first layer. Although the recording methods are discussed primarily with regards to waveguide stacks with two overlapping layers, the basic principle can be applied to waveguide stacks with more than two overlapping layers. Additionally, this principle can be applied to fabricate a variety of different waveguide stack configurations.

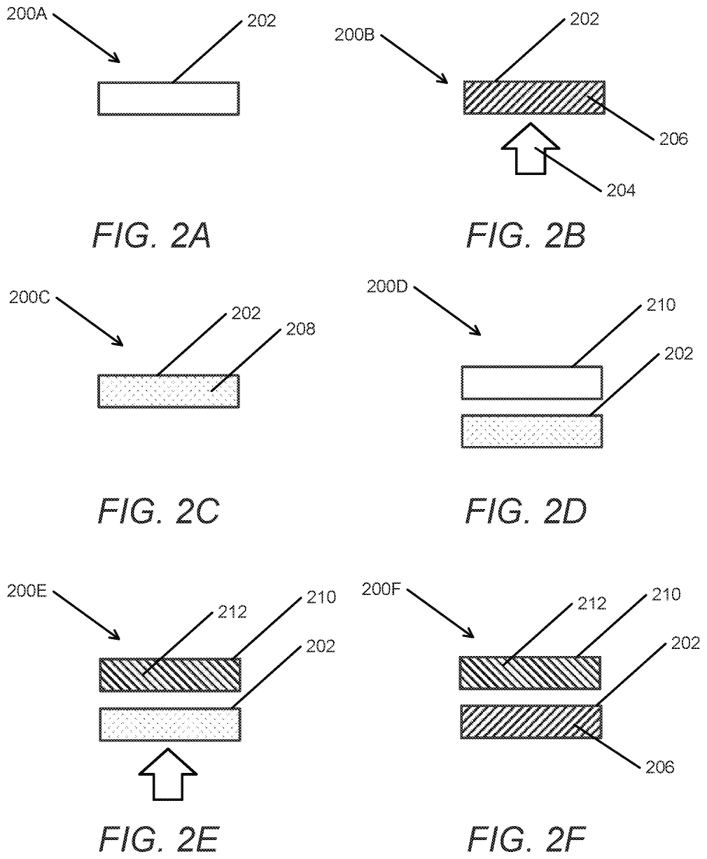

The basic principle of a method for recording a stack of two gratings in accordance with various embodiments of the invention is conceptually illustrated in FIGS. 2A-2F. To simplify the description, the substrates or cells supporting the grating layer are not illustrated in FIGS. 2A-2F. As discussed in the sections above, the gratings can be supported by transparent substrates or encapsulated inside cells made from transparent substrates. FIG. 2A shows the first step 200A in which a first layer 202 of optical recording material is provided. The recording material can include material systems capable of supporting optical structures that can be erased by a stimulus. Any of a variety of different types of optical recording material systems, such as but not limited to the material systems described in the sections above, can be utilized. In many embodiments, the optical recording material includes a mixture of liquid crystal and polymer. In some embodiments, the optical recording material can further include a photosensitive dye, a photoinitiator, a surfactant, a multi-function monomer, and/or nanoparticles.

FIG. 2B shows a second step 200B in which an optical exposure process 204 is applied to the first layer 202 to form a first optical structure 206. In embodiments in which the optical structure is a holographic grating, the exposure process can utilize a crossed-beam holographic recording apparatus. In a number of embodiments, the optical recording process uses beams provided by a holographic master, which may be a Bragg hologram recorded in a photopolymer or an amplitude grating. In some embodiments, the exposure process utilizes a single recording beam in conjunction with a master grating to form an interferential exposure beam. In many embodiments, a contact copying apparatus using a master grating or hologram is used. In several embodiments, the optical recording process uses an apparatus for traversing recording beams with a predefined beam cross section along a predefined path across the optical layer. As can readily be appreciated, optical structures can be recorded using a variety of exposure processes. In addition to the processes described, other industrial processes and apparatuses currently used in the field to fabricate holograms can be used.

Turning now to FIG. 2C, a third step 2000 is illustrated in which the first optical structure 206 is temporarily erased by an external stimulus to produce a cleared first layer 208. External stimulus/stimuli can include optical, thermal, chemical, mechanical, electrical, and/or magnetic stimuli. In many embodiments, the external stimulus is applied at a strength below a predefined threshold to produce optical noise below a predefined level. The specific predefined threshold can depend on the type of material used to form the optical structure. In some embodiments, a sacrificial alignment layer applied to the first optical structure can be used to temporarily erase the first optical structure. In some embodiments, the strength of the external stimulus applied to the first optical structure is controlled to reduced optical noise in the optical device during normal operation. In many embodiments, the optical recording material further includes an additive for facilitating the process of erasing the optical structure, which can include any of the methods described above.

FIG. 2D shows a fourth step 200D in which a second layer 210 of optical recording material is brought into overlap with the exposed first layer 202. In many embodiments, the optical recording materials in both layers are identical. In some embodiments, the first and second layers are fabricated using optical recording materials formulated to be recordable with different spectral and/or angular bandwidths. Such materials can be optimized for different ranges of spectral and/or angular bandwidths.

FIG. 2E shows a fifth step 200E in which an optical exposure process is applied through the cleared first layer 202 and to the second layer 210 to form a second optical structure 212. In many embodiments, during the exposure process, at least one light beam traverses through the first layer to record the second optical structure 212 in the second layer 210.

Finally, FIG. 2F shows a final step 200F in which the first optical structure 206 has been restored to its recorded state. As shown, the resulting device includes two layers with optical structures 206, 212 that are overlaid.

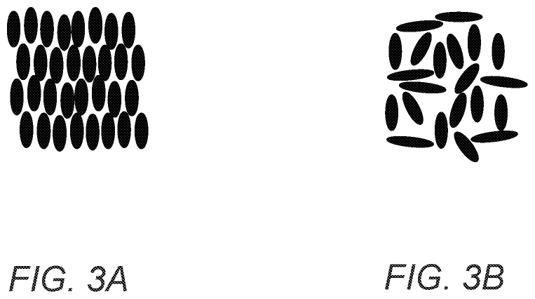

The clearing and restoration of a recorded layer described in the process above can be achieved using many different methods. In many embodiments, the first layer is cleared by applying a stimulus continuously during the recording of the second layer. In other embodiments, the stimulus is initially applied, and the grating in the cleared layer can naturally revert to its recorded state over a timescale that allows for the recording of the second grating. In other embodiments, the layer stays cleared after application of an external stimulus and reverts in response to another external stimulus. In several embodiments, the restoration of the first optical structure to its recorded state can be carried out using an alignment layer or an external stimulus. An external stimulus used for such restoration can be any of a variety of different stimuli, including but not limited to the stimulus/stimuli used to clear the optical structure. Depending on the composition material of the optical structure and layer to be cleared, the clearing process can vary. In embodiments utilizing LC materials, the clearing process can be based on changing the order parameter of the liquid crystals. FIGS. 3A and 3B conceptually illustrate examples of an ordered liquid crystal phase and a disordered liquid crystal phase, respectively. As discussed above, changing the order parameter of the liquid crystals can be achieved in various ways, including but not limited to applying an external stimulus such as but not limited to an electrical stimulus.

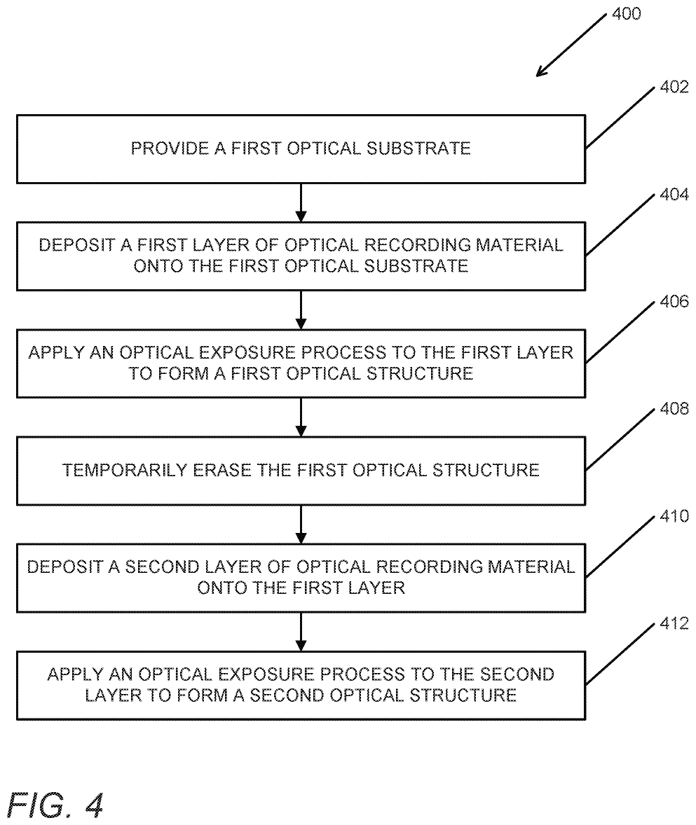

Multi-layer waveguide stacks can be fabricated using a variety of different methods. Additionally, multi-layer waveguide stacks can be constructed with different materials in many different ways. In some embodiments, the waveguide stack includes at least two layers of exposed optical recording material having optical structures. In further embodiments, the two layers of exposed optical recording material are separated by a substrate. As can readily be appreciated, the specific method implemented can depend on the construction of the waveguide stack. FIGS. 4-7 conceptually illustrate several processes for manufacturing different types of waveguide stacks in accordance with various embodiments of the invention.

FIG. 4 conceptually illustrates a flow chart of a process 400 for fabricating a multi-waveguide layer stack in accordance with an embodiment of the invention, similar to the process conceptually illustrated in FIGS. 2A-2F. In the illustrative embodiment of FIG. 4, the method includes fabricating a waveguide stack in which a first optical recording material layer deposited on a substrate is exposed to form a first optical structure, which is temporarily erased so that a second material layer deposited onto the first layer can be exposed using recording beams traversing the first layer.

Turning now to the specifics of FIG. 4, the process 400 can include providing (402) a first optical substrate. Such optical substrates can vary in form and material, such as but not limited to glass and plastics. In many embodiments, the substrates are planar glass plates. In some embodiments, the substrates are curved. A first layer of optical recording material can then be deposited (404) onto the first optical substrate. Material systems capable of being utilized in accordance with various embodiments of the invention can include any material systems in which optical structures can be recorded, such as but not limited to HPDLC material systems. Further examples and variations of such material systems are described in the sections above. Once the optical recording material is deposited, an optical exposure process can be applied (406) to the first layer of optical recording material to form a first optical structure. Optical exposure processes can include conventional techniques used within the field. In many embodiments, a crossed-beam holographic recording apparatus is utilized for the optical exposure process. In some embodiments, a contact copying apparatus using a master grating or hologram is utilized. In several embodiments, an apparatus for traversing light with a predefined beam cross section is utilized. As can readily be appreciated, any optical exposure process can be used, the specific process of which can depend on the specific requirements of a given application—i.e., different types of optical recording materials can have different preferred optical exposure processes. Once the first optical structure is formed in the first layer, the first optical structure can be temporarily erased (408). Erasing the optical structure, or clearing the layer, can be achieved using any of the methods described above, such as but not limited to applying a stimulus to the first layer. A second layer of an optical recording material can be deposited (410) onto the first layer. In several embodiments, the optical recording material of the second layer is identical to the optical recording material of the first layer. In other embodiments, the optical recording materials of the two layers are different. An optical exposure process can be applied (412) to the second layer to form a second optical structure. Exposure processes can include any of the processes utilized for the exposing the first layer. In many embodiments, the exposure process includes traversing at least one light beam through the first layer to record the second optical structure in the second layer. Once the cleared first layer is restored, the resulting device is a two-layer device with each layer having at least one optical structure.

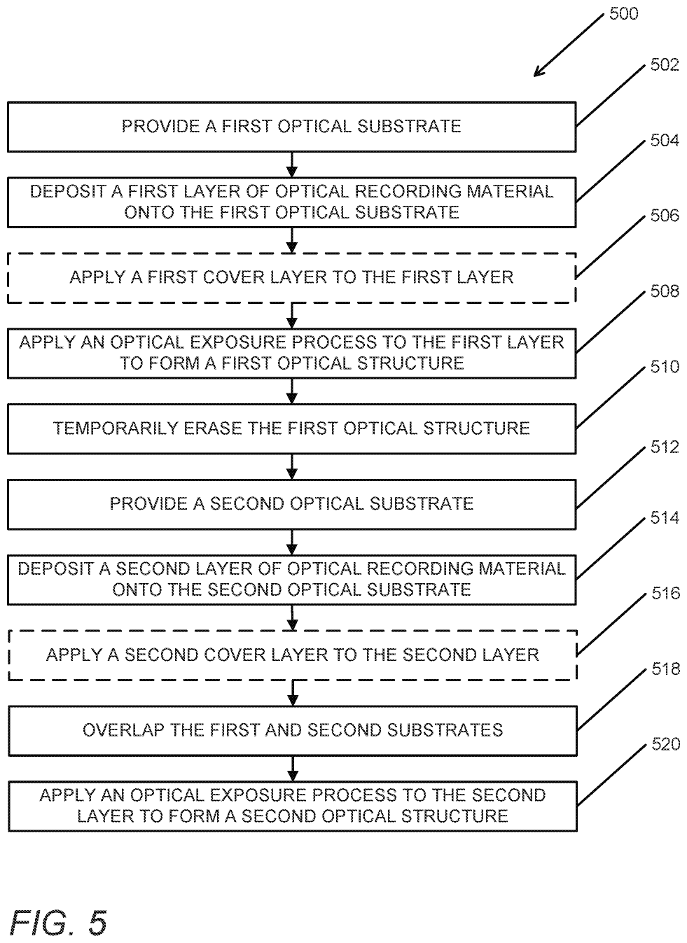

FIG. 5 is a flow chart conceptually illustrating a process 500 for fabricating a multi-waveguide layer stack having two grating layers separated by a substrate in accordance with an embodiment of the invention. As shown, the process 500 can include steps that are similar to the method of FIG. 4. As such, it is to be understood that various ways of performing the steps of the process illustrated in FIG. 4 can be applied similarly to the process 500 of FIG. 5. Referring to FIG. 5, the process 500 can include providing (502) a first optical substrate. Optical substrates can include plates made of transparent materials, such as but not limited to glass and plastics. Additionally, the substrates can be curved or planar. A first layer of optical recording material can be deposited (504) onto the first optical substrate. Various optical recording materials, such as but not limited to HPDLC material systems, can be utilized. A first cover layer can optionally be applied (506) to the first layer. In many embodiments, a cover layer is applied as a substrate. In such cases, the cover layer can include an adhesive layer protected by a peel-off film. In some embodiments, the adhesive layer can be applied to the grating. In several embodiments, the cover layer is a protective layer deposited. Deposition of the cover layer can employ various techniques, such as but not limited to the use of an inkjet coater and other coating processes. Various types of cover layers can also be utilized. In some embodiments, the cover layer is a flexible glass foil, such as but not limited to Corning® Willow® Glass, which is available in various thicknesses including 100 and 200 micrometers. As can readily be appreciated, the specific type of cover layer utilized can depend on the given application. For example, in larger displays, thicker cover glass can be utilized. One example include HUD applications, which can include the use of a 10 mm cover layer. Other materials for cover layers include but are not limited to TAC (cellulose triacetate), TPU (thermoplastic polyurethane), and PET (polyurethane). In several embodiments, the cover layer is a multilayer structure using different materials for greater robustness or for optimizing optical properties, such as but not limited to transmission and/or polarization response. In some applications, the use of a glass or plastic substrate can be eliminated by overcoating the grating layer with a monomeric barrier film that seals the material. In many embodiments, the barrier film is UV curable. In several embodiments, the coating is carried out in a Nitrogen-rich atmosphere. One relevant inkjet coating process, known as the YIELDjet® FLEX system, has been developed by Kateeva Inc. (CA) for OLED display large volume fabrication.

Referring back to FIG. 4, the process 500 can include applying (508) an optical exposure process to the first layer to form a first optical structure. Optical exposure processes can include various holographic recording techniques, such as but not limited to single or two-beam interferential processes. As can readily be appreciated, any optical exposure process can be used and can depend on the specific requirements of a given application. The formed first optical structure can be temporarily erased (510). Erasing the optical structure, or clearing the layer, can be achieved using any of the methods described above, such as but not limited to applying a stimulus to the first layer. A second substrate can be provided (512). A second layer of an optical recording material can be deposited (514) onto the second substrate. In several embodiments, the optical recording material of the second layer is identical to the optical recording material of the first layer. In other embodiments, the optical recording materials of the two layers are different. A second cover layer (516) can optionally be applied to the second layer. In many embodiments, the second cover layer is made of a material identical to the first cover layer. The first and second substrates can be overlaid (518) with each other. In several embodiments, the second substrate is laterally or rotationally displaced relative to the first substrate. An optical exposure process can be applied (520) to the second layer to form a second optical structure. Exposure processes can include any of the processes utilized for the exposing the first layer. In many embodiments, the exposure process includes traversing at least one light beam through the first layer to record the second optical structure in the second layer.

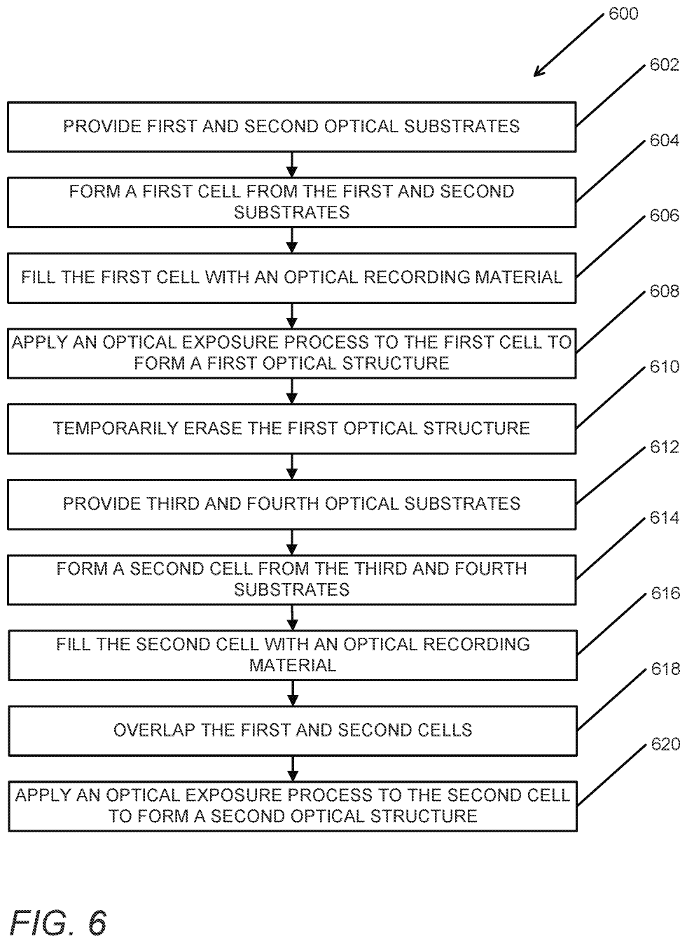

FIG. 6 is a flow chart conceptually illustrating a process 600 for fabricating a multi-waveguide layer stack in which each grating layer is encapsulated within a cell in accordance with an embodiment of the invention. Referring to FIG. 6, the process 600 can include providing (602) a first optical substrate and a second optical substrate. Any type of optical substrates, such as those described in the sections above, can be utilized. In many embodiments, the optical substrates are transparent. A first cell can be formed (604) from the first and second substrates. The first cell can be filled (606) with a first optical recording material. Various optical recording materials, such as but not limited to HPDLC material systems, can be utilized. As can readily be appreciated, the formation of a cell containing optical recording material can be achieved in many different ways. In some embodiments, the cell is formed by depositing the optical recording material onto a first substrate. The deposition technique can include but are not limited to inkjet printing, spin-coating, and various additive manufacturing depositions techniques. A second substrate can be placed on top of the deposited material and the various layers can be laminated to form a cell. Referring back to FIG. 6, the process 600 can include applying (608) an optical exposure process to the first cell to form a first optical structure. As can readily be appreciated, any optical exposure process can be used and can depend on the specific requirements of a given application. The first optical structure can be temporarily erased (610). Erasing the optical structure, or clearing the layer, can be achieved using any of the methods described above, such as but not limited to applying a stimulus to the first layer. A third optical substrate and a fourth optical substrate can be provided (612). A second cell can be formed (614) from the third and fourth substrates. The second cell can be filled (616) with an optical recording material. In several embodiments, the second cell is filled with a type of optical recording material that is identical to the optical recording material in the first cell. The first and second cell can be overlaid (618) with each other. In several embodiments, the second cell is laterally or rotationally displaced relative to the first cell. An optical exposure process can be applied (620) to the optical recording material of the second cell to form a second optical structure. Various optical exposure processes, including but not limited to the exposure processes for the first cell, can be utilized.

Although FIGS. 2A-2F and 4-6 conceptually illustrate specific processes for fabricating optical structures in a stack of two layers of recording material, it is to be understood that the basic principle can be applied to many different fabrication processes and variations of such in accordance with various embodiments of the invention. For example, the processes described above can be extended to allow for the recording of stacks with more than two layers. In many embodiments, the processes described can be implemented iteratively to record optical structures in a stack of more than two layers of recording material. In such embodiments, a third layer of optical recording material can be deposited and an optical exposure process can be applied to the third layer to form an optical structure using a light beam that traverses through the erased first and second layers. In embodiments with processes for fabricating a waveguide stack with more than two layers, the methods for temporarily clearing the optical structures can be applied to more than one layer simultaneously. In some embodiments, layers and substrates that provide a waveguide layer can be separated from other waveguide layers by air gaps or layers of low refractive index material. In several embodiments, nanoporous material can be used to separate the waveguide layers.

As described above, various steps in the processes conceptually illustrated in FIGS. 5 and 6 can be performed similarly to their counterparts in the process conceptually illustrated in FIG. 4. Additionally, some steps can be performed independent of previous steps. Such steps can be performed concurrently or sequentially with other steps. For example, in the process of FIG. 6, the second cell can be formed concurrently with, subsequent to, or prior to the formation of first cell. In some embodiments, the order of some of the steps used in the above processes can be changed.

The above described processes can further include at least one of the steps of: applying electrodes to substrate surfaces for switching optical structures; providing an air gap in the stack of layers; applying a layer of low refractive index material; applying a polarization control layer; and/or applying a liquid crystal alignment layer. In such embodiments where a liquid crystal alignment layer is applied, the liquid crystal alignment layer can be a liquid crystal polymer or a linearly photopolymerizable (“LPP”) material. In embodiments where a polarization layer is applied, the polarization control layer can be a half wave plate or a quarter waveplate.

It is to be understood that the various components, such as optical substrates and optical recording materials, utilized in the processes can differ from application to application. Even among a single application, different materials can be used. For example, in a given application, optical substrates utilized can include plates made of a transparent material, such as glass or plastic. The plastic substrates can be fabricated in various ways, such as but not limited to using the materials and processes disclosed in PCT Application No.: PCT/GB2012/000680, entitled IMPROVEMENTS TO HOLOGRAPHIC POLYMER DISPERSED LIQUID CRYSTAL MATERIALS AND DEVICES, the disclosure of which is hereby incorporated by reference in its entirety. In many embodiments, at least one of the substrates can be curved and fabricated from various materials, such as but not limited to plastic and various flexible materials. In some embodiments, the optical layer is formed into a wedge by tilting one of the substrates. In several embodiments, a wedged optical layer is formed by controlling the layer thickness in a coating process. In various embodiments, substrates of similar materials are used. In other embodiments, different substrate materials can be used in the same application.

The same principle discussed above can be applied to the optical recording materials. Various optical recording materials, such as but not limited to HPDLC mixtures, can be used in the processes described above. In several embodiments, the layers having optical structures can be formed from the same type of optical recording material. In other embodiments, each layer is formed from an optical recording material that is formularized for a different application that can differ from the formulation of the optical recording material in a different layer. In many embodiments, the optical recording material can be a low haze material, such as those described in U.S. patent application Ser. No. 16/242,943, entitled LOW HAZE LIQUID CRYSTAL MATERIALS, the disclosure of which is hereby incorporated by reference in its entirety. In some embodiments, the optical recording material can be one optimized for recording holographic gratings with high sensitivity to S and P polarized light, such as those described in U.S. patent application Ser. No. 16/242,954, entitled LIQUID CRYSTAL MATERIALS AND FORMULATIONS, the disclosure of which is hereby incorporated by reference in its entirety.

Many embodiments in accordance with the invention can be applied in various mass production processes. In some embodiments, fabrication processes, such as those described above, are implemented within a roll-to-roll fabrication process. In several embodiments, the processes can be used in the manufacturing of an environmentally isolated waveguide display according to the embodiments and teachings of U.S. patent application Ser. No. 15/543,016, entitled ENVIRONMENTALLY ISOLATED WAVEGUIDE DISPLAY. The disclosure of U.S. patent application Ser. No. 15/543,016 is hereby incorporated by reference in its entirety for all purposes. In a number of embodiments, the fabrication processes can be applied in the manufacture of a waveguide integrated within a window as disclosed in the above reference.

In some embodiments, SBGs are recorded in a uniform modulation material, such as polymer liquid crystal polymer slices (“POLICRYPS”) or polymer liquid crystal polymer holograms electrically manageable (“POLIPHEM”) mixtures having a matrix of solid liquid crystals dispersed in a liquid polymer. The SBGs can be switching or non-switching in nature. In its non-switching form, an SBG has the advantage over conventional holographic photopolymer materials of providing high refractive index modulation due to its liquid crystal component. Exemplary uniform modulation liquid crystal-polymer material systems, characterized by high refractive index modulation (and hence high diffraction efficiency) and low scatter, are disclosed in United State Patent Application Publication No.: 2007/0019152 by Caputo et al. and PCT Application No.: PCT/EP2005/006950 by Stumpe et al., the disclosures of which are incorporated herein by reference in their entireties for all purposes.

In many embodiments, the gratings are recorded in a reverse mode HPDLC, which differs from conventional HPDLC in that the grating is passive when no electric field is applied and becomes diffractive in the presence of an electric field. The reverse mode HPDLC can be based on any recipes and processes, such as those described in PCT Application No.: PCT/GB2012/000680, entitled IMPROVEMENTS TO HOLOGRAPHIC POLYMER DISPERSED LIQUID CRYSTAL MATERIALS AND DEVICES, the disclosure of which is hereby incorporated by reference in its entirety. The grating can be recorded in any of the above material systems and used in a passive (non-switching) mode. The fabrication process can be identical to that used for switched gratings but with the electrode coating stage being omitted.

Although specific fabrication processes are discussed above, many different processes can be implemented in accordance with many different embodiments of the invention. It is therefore to be understood that the present invention can be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents. Although specific embodiments have been described in detail in this disclosure, many modifications are possible (for example, variations in sizes, dimensions, structures, shapes and proportions of the various elements, values of parameters, mounting arrangements, use of materials, colors, orientations, etc.). For example, the position of elements may be reversed or otherwise varied and the nature or number of discrete elements or positions may be altered or varied. Accordingly, all such modifications are intended to be included within the scope of the present disclosure. The order or sequence of any process or method steps may be varied or re-sequenced according to alternative embodiments. Other substitutions, modifications, changes, and omissions may be made in the design, operating conditions and arrangement of the exemplary embodiments without departing from the scope of the present disclosure.

### DOCTRINE OF EQUIVALENTS

While the above description contains many specific embodiments of the invention, these should not be construed as limitations on the scope of the invention, but rather as an example of one embodiment thereof. It is therefore to be understood that the present invention may be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. A method of fabricating an optical element, the method comprising:
providing a first optical substrate;
depositing a first layer of a first optical recording material onto the first optical substrate;
applying an optical exposure process to the first layer to form a first optical structure;
temporarily erasing the first optical structure;
depositing a second layer of a second optical recording material; and
applying an optical exposure process to the second layer to form a second optical structure, wherein the optical exposure process comprises using at least one light beam traversing the first layer.

2. The method of claim 1, further comprising:
providing a second optical substrate, wherein the second layer is deposited onto the second optical substrate; and
overlapping the second optical substrate with the first optical substrate.

3. The method of claim 2, wherein the second optical substrate is laterally or rotationally displaced relative to the first optical substrate.

4. The method of claim 1, further comprising:
applying a first cover layer to the first layer; and
applying a second cover layer to the second layer.

5. The method of claim 1, wherein the at least one light beam is provided by an apparatus selected from the group consisting of: a crossed-beam holographic recording apparatus; a contact copying apparatus using a master grating or hologram; and an apparatus for traversing light with a predefined beam cross section.

6. The method of claim 1, wherein the first optical structure is temporarily erased by applying an external stimulus.

7. The method of claim 6, wherein the external stimulus comprises a stimulus selected from the group consisting of: an optical stimulus; a thermal stimulus; a chemical stimulus; a mechanical stimulus; an electrical stimulus; and a magnetic stimulus.

8. The method of claim 6, wherein the external stimulus is applied at a strength below a predefined threshold to produce optical noise below a predefined level.

9. The method of claim 1, further comprising:
temporarily erasing the second optical structure;
depositing a third layer of a third optical recording material;
applying an optical exposure process to the third layer to form a third optical structure using at least one light beam traversing the first layer and the second layer.

10. The method of claim 1, wherein at least one of the first and second optical structures modifies at least one of: phase; amplitude; and wavefront of incident light.

11. The method of claim 1, wherein the first optical recording material and the second optical recording material comprise different material formulations.

12. The method of claim 1, wherein the first optical recording material comprises a mixture of liquid crystal and polymer; and wherein the first optical structure comprises at least one grating.

13. The method of claim 12, wherein the first optical recording material further comprises at least one of: a LPP; a dye; a photoinitiator; a surfactant; a multi-function monomer; and nanoparticles.

14. The method of claim 12, wherein temporarily erasing the first optical structure comprises changing the order parameter of the liquid crystal.

15. The method of claim 1, wherein the first optical recording material comprises a liquid crystal, polymer, and an additive for temporarily erasing the first optical structure.

16. The method of claim 1, wherein the first optical recording material is deposited onto the first optical substrate using spin coating or inkjet printing.

17. The method of claim 1, wherein the first optical substrate is curved.

18. The method of claim 1, further comprising at least one of the steps of: forming an air gap; applying a layer of low refractive index material; applying a polarization control layer; and applying a liquid crystal alignment layer.

19. The method of claim 1, forming part of a roll-to-roll fabrication process.

20. A method of fabricating an optical element, the method comprising:
providing first and second optical substrates;
forming a first cell from the first and second substrates;
filling the first cell with a first optical recording material;
applying an optical exposure process to the first cell to form a first optical structure;
temporarily erasing the first optical structure;
providing third and fourth optical substrates;
forming a second cell from the third and fourth substrates;
filling the second cell with a second optical recording material;
overlapping the first and second cells; and
applying an optical exposure process to the second layer to form a second optical structure, wherein the optical exposure process comprises using at least one light beam traversing the first layer.
